(19) United States
(12) Patent Application Publication
(10) Pub. No.: US 2022/0376535 A1
(43) Pub. Date: Nov. 24, 2022

(54) CHARGING NOTIFICATIONS FOR A BATTERY PACK CHARGER

(71) Applicant: MILWAUKEE ELECTRIC TOOL CORPORATION, Brookfield, WI (US)

(72) Inventors: Kyle Reeder, Waukesha, WI (US); Christopher S. Spaulding, Green Bay, WI (US); Matthew Post, Milwaukee, WI (US); Samuel B. Petre, Brookfield, WI (US); Shreyas Sridar, Milwaukee, WI (US); Isabel M. Lloyd, West Allis, WI (US)

(21) Appl. No.: 17/748,828

(22) Filed: May 19, 2022

Related U.S. Application Data
(60) Provisional application No. 63/190,401, filed on May 19, 2021.

(51) Int. Cl. H02J 7/00; G01R 31/3835

(52) U.S. Cl. CPC H02J 7/0048; H02J 7/0013; H02J 7/00036; G01R 31/3835

(57) ABSTRACT

Systems and methods for providing notifications regarding battery pack charging status. One charging system includes a battery charger and an external device. The battery charger includes a housing, a battery pack interface, a wireless communication controller, and a charger controller. The charger controller receives status information associated with power tool battery packs and transmits the status information to an external device. The external device includes a display and an external device controller. The external device controller receives the status information from the charger controller and controls the display to display the status information via a user interface.

### RELATED APPLICATIONS

This application claims the benefit of U.S. Provisional Patent Application No. 63/190,401, filed May 19, 2021, the entire content of which is hereby incorporated by reference.

### SUMMARY

Embodiments described herein provide systems and methods for providing notifications related to battery pack charging status.

Charging systems described herein include a battery charger and an external device. The battery charger includes a housing, a battery pack interface, a wireless communication controller, and a charger controller. The battery pack interface is configured to receive a plurality of power tool battery packs. The wireless communication controller is configured to communicate with the external device. The charger controller is connected to the battery pack interface and the wireless communication controller. The charger controller is configured to receive status information associated with each of the plurality of power tool battery packs and transmit, with the wireless communication controller, the status information to an external device. The external device includes a display and an external device controller connected to the display. The external device controller is configured to receive the status information from the charger controller and control the display to display the status information via a user interface.

Methods for notifying battery pack status described herein include receiving, with a battery pack charger, status information associated with a plurality of power tool battery packs connected to the battery pack charger, wherein the battery pack charger includes a housing, transmitting, with a wireless communication controller, the status information to an external device, receiving, with the external device, the status information from the charger controller, and controlling, with the external device, a display to display the status information via a user interface.

Battery chargers described herein include a housing, a display, a battery pack interface, and a charger controller. The battery pack interface is configured to receive a power tool battery pack. The charger controller is connected to the battery pack interface and the display. The charger controller is configured to receive status information associated with the power tool battery pack and provide, one the display, a plurality of indicators indicative of the status information.

Before any embodiments are explained in detail, it is to be understood that the embodiments are not limited in its application to the details of the configuration and arrangement of components set forth in the following description or illustrated in the accompanying drawings. The embodiments are capable of being practiced or of being carried out in various ways. Also, it is to be understood that the phraseology and terminology used herein are for the purpose of description and should not be regarded as limiting. The use of “including,” “comprising,” or “having” and variations thereof are meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings.

In addition, it should be understood that embodiments may include hardware, software, and electronic components or modules that, for purposes of discussion, may be illustrated and described as if the majority of the components were implemented solely in hardware. However, one of ordinary skill in the art, and based on a reading of this detailed description, would recognize that, in at least one embodiments, the electronic-based aspects may be implemented in software (e.g., stored on non-transitory computer-readable medium) executable by one or more processing units, such as a microprocessor and/or application specific integrated circuits (“ASICs”). As such, it should be noted that a plurality of hardware and software-based devices, as well as a plurality of different structural components, may be utilized to implement the embodiments. For example, “servers” and “computing devices” described in the specification can include one or more processing units, one or more computer-readable medium modules, one or more input/output interfaces, and various connections (e.g., a system bus) connecting the components.

Other features and aspects will become apparent by consideration of the following detailed description and accompanying drawings.

### BRIEF DESCRIPTION OF THE DRAWINGS

FIG. 1 illustrates a battery pack charger, according to embodiments described herein.

FIG. 2 illustrates a battery pack charger, according to embodiments described herein.

FIG. 3 illustrates a battery pack charger, according to embodiments described herein.

FIG. 4 illustrates a battery pack charger, according to embodiments described herein.

FIG. 5 illustrates a battery pack charger, according to embodiments described herein.

FIG. 6 illustrates a control system for the battery pack chargers of FIG. 1 to FIG. 5, according to embodiments described herein.

FIG. 7 illustrates a wireless communication controller for the chargers of FIG. 1 to FIG. 5, according to embodiments described herein.

FIG. 8 illustrates a communication network for the chargers of FIG. 1 to FIG. 5, according to embodiments described herein.

FIG. 9 illustrates a dashboard integrated into the chargers of FIG. 1 to FIG. 5, according to embodiments described herein.

FIG. 10 illustrates user interfaces of a mobile device for controlling the chargers of FIG. 1 to FIG. 5, according to embodiments described herein.

FIG. 11 illustrates a method of providing a notification of battery pack status, according to embodiments described herein.

### DETAILED DESCRIPTION

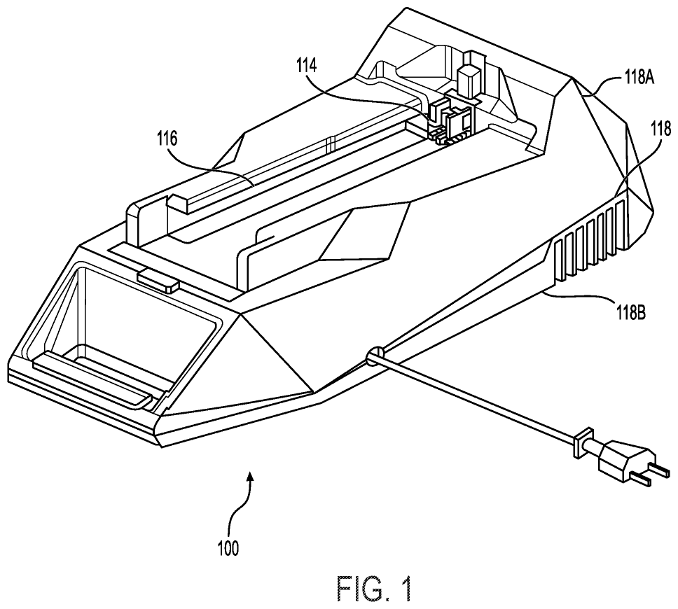

FIG. 1 illustrates a battery pack charger 100. The battery pack charger 100 has a battery pack charger housing 118 including a top housing portion 118a and a bottom housing portion 118b. The battery pack charger 100 is configured to receive AC power from an AC power source (e.g., a grid-connected wall outlet or AC generator) to charge a battery pack. The battery pack charger 100 includes a physical battery pack interface 116 configured to receive and retain a power tool battery pack (e.g., via rails that slidingly engage the corresponding rails of the battery pack) and an electrical battery pack interface 114 (e.g., terminals) configured to engage corresponding electrical contacts of the battery pack. In some embodiments, the battery pack charger 100 includes additional interfaces 114 and 116 such that it is configured to receive and charge multiple battery packs (e.g., receive and charge two battery packs simultaneously). The battery pack charger 100 may include a screen integrated on the housing 118, described in more detail below.

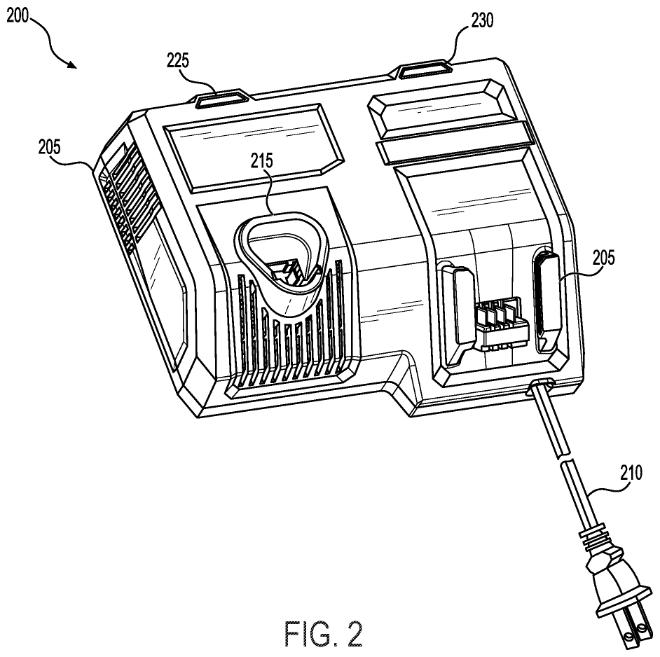

FIG. 2 illustrates a battery pack charger or charger 200. The battery pack charger 200 includes a housing portion 205 and an AC input power plug 210. The battery pack charger 200 can be configured to charge one or more battery packs having one or more nominal voltage values. For example, the battery pack charger 200 illustrated in FIG. 2 is configured to charge a first type of battery pack using a first battery pack receiving portion or interface 215 and a second type of battery pack using a second battery pack receiving portion or interface 220. The first type of battery pack is, for example, a 12V battery pack having a stem that is inserted into the first battery pack receiving portion 215. The second type of battery pack is, for example, an 18V battery pack having a plurality of rails for slidably attaching the battery pack in the second battery pack receiving portion 220.

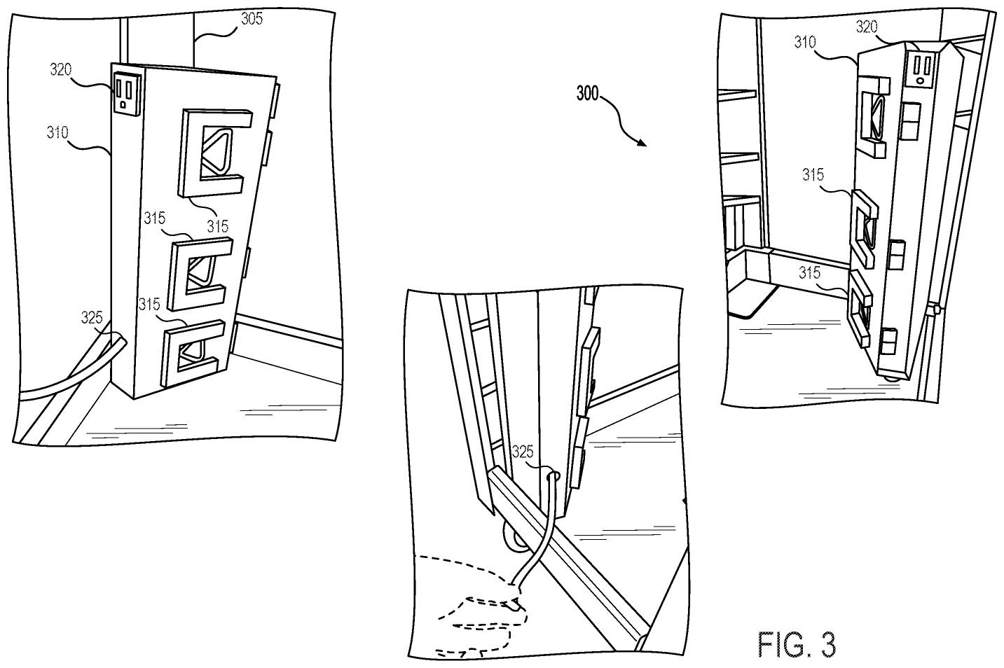

FIG. 3 illustrates a battery pack charger 300 according to another embodiment. Specifically, FIG. 3 illustrates a charging module for a mobile work cart. The charging module is removably mounted to a leg 305 and/or a side surface of the mobile work cart. More specifically, the charging module is shaped to fit in an inside corner of a leg 305 of the mobile work cart. The charging module includes a main body 310 that is generally rectangular. The main body 310 is relatively compact, such that the charging module comprises minimal space on the mobile work cart. The main body 310 includes a front surface, a back surface, two side surfaces, a top surface, and a bottom surface. The front surface includes various charging bays 315 for receiving a battery pack (e.g., a power tool battery pack). In the illustrated embodiment, the front surface includes three charging bays 315 configured to receive 12 Volt and/or 18 Volt battery packs. In some embodiments, the charging module includes a screen (not shown) integrated on a surface of the main body.

At least one of the side surfaces includes at least one port 320. The illustrated ports 320 are AC pass-through ports. The AC pass-through ports 320 are connectable to tools and/or equipment including an AC connector. In the illustrated embodiments, the battery pack charger 300 includes two AC pass-through ports 320. However, in alternative embodiments, the battery pack charger 300 may include fewer or additional AC pass-through ports 320. The side surface(s) and top surface additionally include an aperture 325 extending therethrough. The aperture 325 is shaped and sized to receive a cord. Specifically, the aperture 325 on the side surface is positioned at a height which allows the exiting cord to clear a bottom lip of the mobile work cart. This configuration reduces potential safety hazards for a user (e.g., tripping). The bottom surface of the main body includes several feet (not shown) mounted to the surface. The feet provide clearance between the bottom surface and the bottom of the cart.

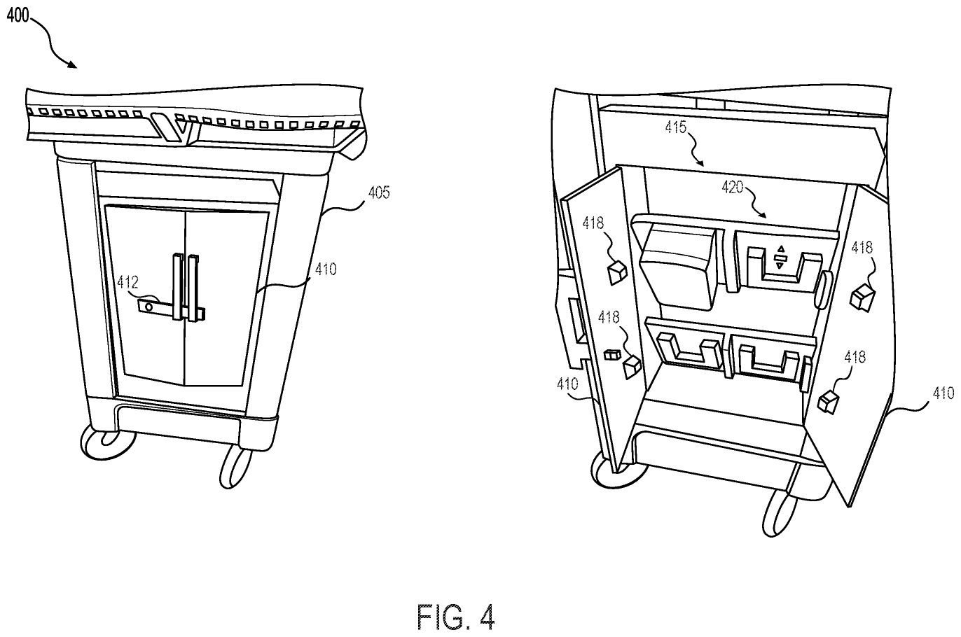

FIG. 4 illustrates a battery pack charger 400 according to another embodiment. Specifically, FIG. 4 illustrates a “lock pop and drop it” concept for a charging module for a mobile work cart 405. The charging module is removably coupled underneath the mobile work cart (e.g., on a lower shelf of the mobile work cart). More specifically, the battery pack charger 400 is shaped and sized to snugly fit underneath a mobile work cart 405 and is secured to sides of the mobile work cart 405. The battery pack charger 400 is configured as a rectangular cabinet including two doors 410 movable between a closed position and an open position. The cabinet additionally forms a storage chamber 415 for storing various power sources (e.g., battery packs). The doors 410 including a locking mechanism 412 for securing the doors in the closed position. Inner surfaces of the doors 410 include tabs 418, or protrusions, extending into the storage chamber. In some embodiments, the charging module includes a screen (not shown), which may be integrated on one of the doors 410.

With continued reference to FIG. 4, the storage chamber includes various charging bays 420 formed therein for receiving at least one battery pack (e.g., a power tool battery pack). The charging bays 420 are generally pivotable. When the doors are closed, the tabs 418 engage each of the charging bays 420 and pivot the charging bays 420 to a stored (e.g., parallel) position relative to the doors 410.

Alternatively, when a user opens the doors 410, the tabs 418 disengage the charging bays 420, thereby causing the charging bays 420 to pivot downward to an angled position. When in the angled position, battery packs positioned on the charging bays 420 are prevented from slipping off of the charging bays 420. The pivoting charging bays 420 allow for compact storage (e.g., when the doors 410 are closed and the charging bays 420 are in the stored position), and allow for easy access for the user (e.g., when the doors 410 are open and the charging bays 420 are in the angled position). In the illustrated embodiments, the storage chamber 415 includes four charging bays 420. However, in other embodiments, the storage chamber 415 may include fewer or additional charging bays 420.

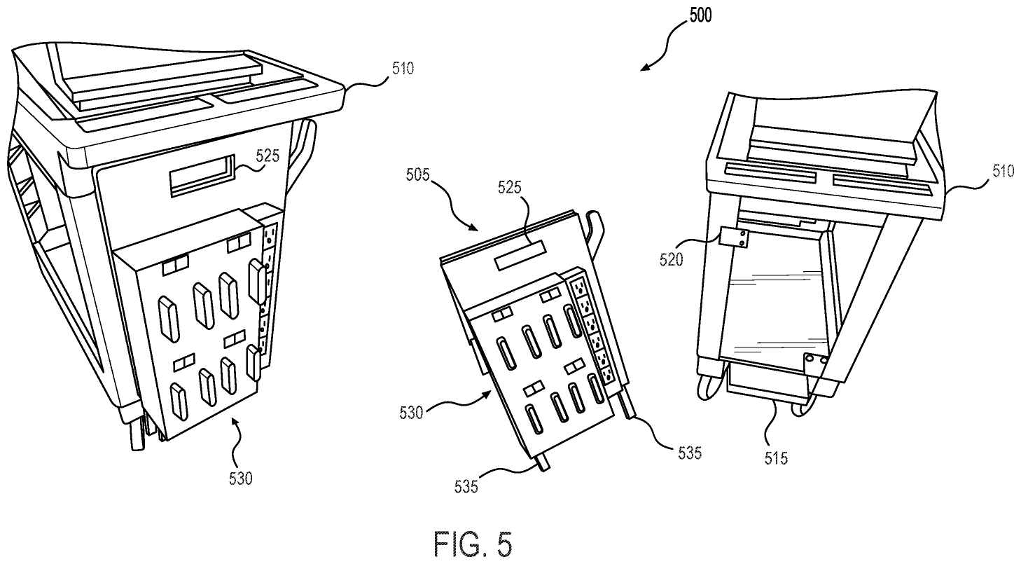

FIG. 5 illustrates a battery pack charger 500 according to another embodiment. Specifically, FIG. 5 illustrates a “sandwich board” concept for a charging module 505 for a mobile work cart 510. The charging module 505 is removably coupled to a side surface of the mobile work cart 510. Specifically, the charging module 505 is shaped and sized to fit underneath a handle of a mobile work cart 510. The charging module 505 includes a base 515 and a working surface pivotable relative to the base 515 about a hinge 520. The base 515 and the working surface are identically shaped and sized and the working surface is configured to rest on top of the base 515 when mounted to the mobile work cart 510. An aperture extends through the base and the working surface, thereby forming a handle 525 graspable by the user. The user may grasp the handle 525 for support or when transporting the charging module.

An upper surface of the working surface includes charging bays 530 configured to receive various battery packs. Specifically, the working surface shown in FIG. 5 includes four charging bays 530 configured to receive battery packs. However, in alternative embodiments, the working surface may include fewer or additional charging bays 530. In some embodiments, the charging module 505 includes a screen (not shown) integrated on the upper surface.

Distal ends of the base and the working surface include legs 535 extending therefrom and configured to support the charging module 505 on the ground. Specifically, when the charging module 505 is removed from the mobile work cart 510, the user may pivot the working surface away from the base 515 and position the legs 535 on the ground to support the charging module 505 in an upright, self-supporting position.

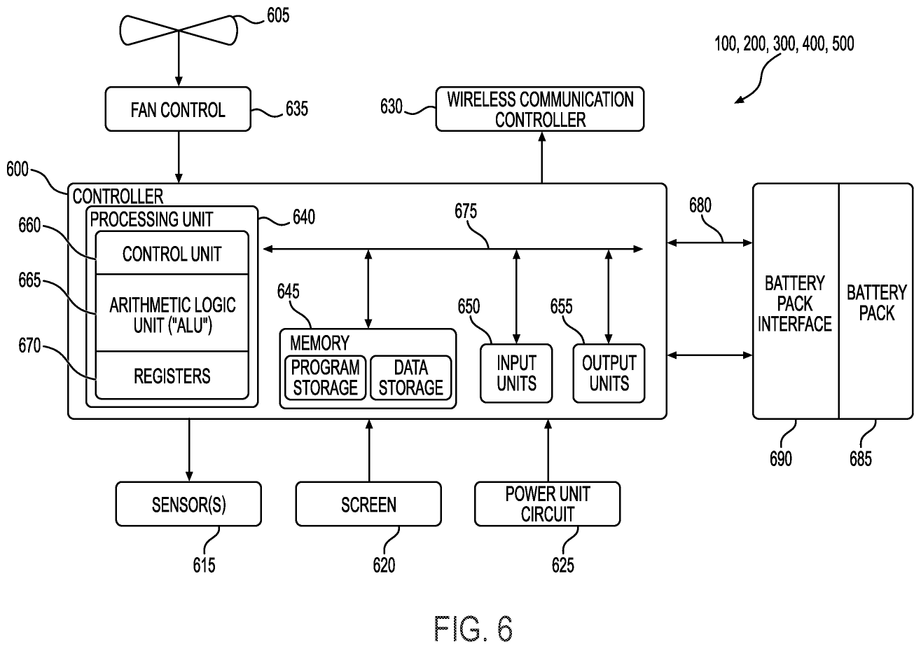

FIG. 6 illustrates a control system for the battery pack charger 100, 200, 300, 400, 500. The control system includes a controller 600 (e.g., a charger controller). The controller 600 is electrically and/or communicatively connected to a variety of modules or components of the battery pack charger 100-500. For example, the illustrated controller 600 is electrically connected to a fan 605, a battery pack interface 690, one or more sensors or sensing circuits 615 (e.g., current sensors, temperature sensors, etc.), a display or screen 620, a power input circuit 625, a wireless communication controller 630, and a fan control module or circuit 635. The controller 600 includes combinations of hardware and software that are operable to, among other things, control the operation of the battery pack charger 100-500, determine a charging status of a battery pack 685 coupled to the battery pack interface 690, provide information via the screen 620, and the like.

The controller 600 includes a plurality of electrical and electronic components that provide power, operational control, and protection to the components and modules within the controller 600 and/or battery pack charger 100-500. For example, the controller 600 includes, among other things, a processing unit 640 (e.g., a microprocessor, a microcontroller, an electronic controller, an electronic processor, or another suitable programmable device), a memory 645, input units 650, and output units 655. The processing unit 640 includes, among other things, a control unit 660, an arithmetic logic unit (“ALU”) 665, and a plurality of registers 670 (shown as a group of registers in FIG. 6), and is implemented using a known computer architecture (e.g., a modified Harvard architecture, a von Neumann architecture, etc.). The processing unit 640, the memory 645, the input units 650, and the output units 655, as well as the various modules or circuits connected to the controller 600 are connected by one or more control and/or data buses (e.g., common bus 675). The control and/or data buses are shown generally in FIG. 6 for illustrative purposes.

The memory 645 is a non-transitory computer readable medium and includes, for example, a program storage area and a data storage area. The program storage area and the data storage area can include combinations of different types of memory, such as a ROM, a RAM (e.g., DRAM, SDRAM, etc.), EEPROM, flash memory, a hard disk, an SD card, or other suitable magnetic, optical, physical, or electronic memory devices. The processing unit 640 is connected to the memory 645 and executes software instructions that are capable of being stored in a RAM of the memory 645 (e.g., during execution), a ROM of the memory 645 (e.g., on a generally permanent basis), or another non-transitory computer readable medium such as another memory or a disc. Software included in the implementation of the battery pack charger 100-500 can be stored in the memory 645 of the controller 600. The software includes, for example, firmware, one or more applications, program data, filters, rules, one or more program modules, and other executable instructions. The controller 600 is configured to retrieve from the memory 645 and execute, among other things, instructions related to the control processes and methods described herein. In other constructions, the controller 600 includes additional, fewer, or different components.

The one or more sensors 615 are configured to sense operational parameters of the battery pack 685. For example, the one or more sensors 615 may include voltage sensors configured to sense a charge voltage of the battery pack 685. The one or more sensors 615 may include current sensors configured to sense a charging current provided to the battery pack 685. The one or more sensors 615 may include temperature sensors configured to sense a temperature of the battery pack 685. In embodiments where multiple battery packs 685 are connected to the battery pack charger 100, 200, 300, 400, 500, the controller 600 may receive information associated with operational parameters of each battery pack 685 connected to the battery pack charger 100, 200, 300, 400, 500 via the battery pack interface 690.

The battery pack interface 690 includes a combination of mechanical components (e.g., rails, grooves, latches, etc.) and electrical components (e.g., one or more terminals) configured to and operable for interfacing (e.g., mechanically, electrically, and communicatively connecting) the battery pack charger 100-500 with a battery pack 685. The battery pack interface 690 may be, for example, a combination of an electrical battery pack interface and a physical battery pack interface. The battery pack interface 690 is also configured to communicatively connect to the controller 600 via a communications line 680. For example, the battery pack 685 may communicate charging parameters and operational parameters to the controller 600 via the communications line 680.

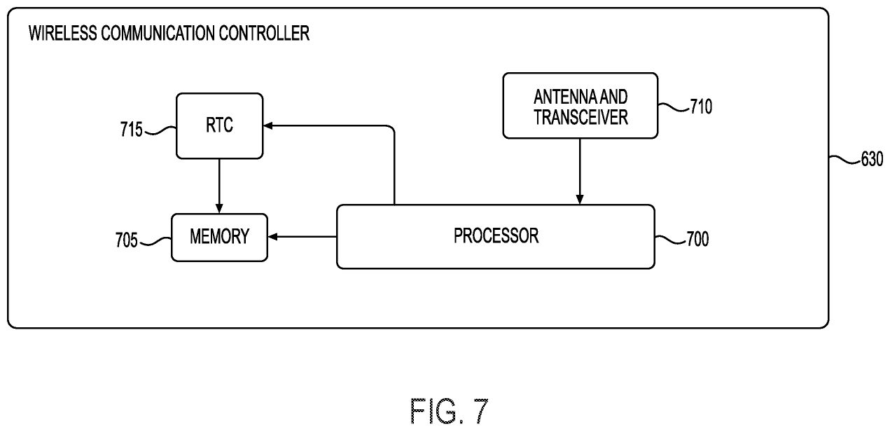

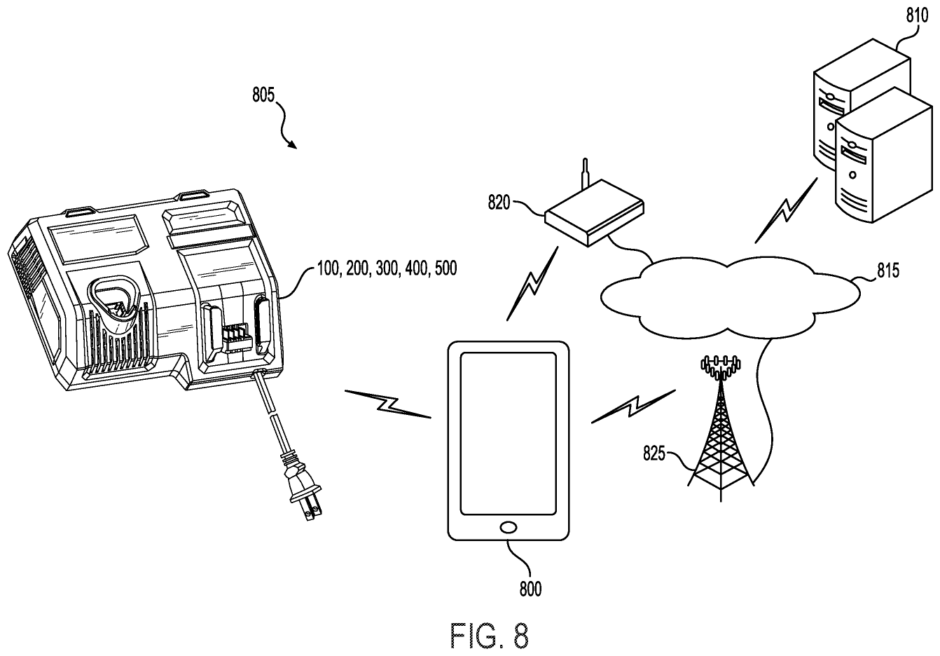

FIG. 7 illustrates a wireless communication controller 630 for the battery pack charger 100-500. The wireless communication controller 630 includes a processor 700, a memory 705, an antenna and transceiver 710, and a real-time clock (RTC) 715. The wireless communication controller 630 enables the battery pack charger 100-500 to communicate with an external device 800 (see, e.g., FIG. 8). The radio antenna and transceiver 710 operate together to send and receive wireless messages to and from the external device 800 and the processor 700. The memory 705 can store instructions to be implemented by the processor 700 and/or may store data related to communications between the battery pack charger 100-500 and the external device 800, or the like. The processor 700 for the wireless communication controller 630 controls wireless communications between the battery pack charger 100-500 and the external device 800. For example, the processor 700 associated with the wireless communication controller 630 buffers incoming and/or outgoing data communicates with the controller 600, and determines the communication protocol and/or settings to use in wireless communications. The communication via the wireless communication controller 630 can be encrypted to protect the data exchanged between the battery pack charger 100-500 and an external device 800 from third parties.

In the illustrated embodiment, the wireless communication controller 630 is a Bluetooth® controller. The Bluetooth® controller communicates with the external device 800 employing the Bluetooth® protocol. Therefore, in the illustrated embodiment, the external device 800 and the battery pack charger 100-500 are within a communication range (i.e., in proximity) of each other while they exchange data. In other embodiments, the wireless communication controller 630 communicates using other protocols (e.g., Wi-Fi, ZigBee, a proprietary protocol, etc.) over different types of wireless networks. For example, the wireless communication controller 630 may be configured to communicate via Wi-Fi through a wide area network such as the Internet or a local area network, or to communicate through a piconet (e.g., using infrared or NFC communications).

In some embodiments, the network is a cellular network, such as, for example, a Global System for Mobile Communications (“GSM”) network, a General Packet Radio Service (“GPRS”) network, a Code Division Multiple Access (“CDMA”) network, an Evolution-Data Optimized (“EV-DO”) network, an Enhanced Data Rates for GSM Evolution (“EDGE”) network, a 3GSM network, 4GSM network, a 4G LTE network, 5G New Radio, a Digital AMPS (“IS-136/TDMA”) network, or an Integrated Digital Enhanced Network (“iDEN”) network, etc.

The wireless communication controller 630 is configured to receive data from the controller 600 and relay the information to the external device 800 via the antenna and transceiver 710. In a similar manner, the wireless communication controller 630 is configured to receive information (e.g., configuration and programming information) from the external device 800 via the antenna and transceiver 710 and relay the information to the controller 600.

The RTC 715 increments and keeps time independently of the other components. Having the RTC 715 as an independently powered clock (e.g., by coin cell battery) enables time stamping of operational data (stored in memory 705 for later export).

FIG. 8 illustrates a communication system 805. The communication system 805 includes battery pack charger 100-500 and the external device 800. Each battery pack charger 100-500 and the external device 800 can communicate wirelessly while they are within a communication range of each other. Each battery pack charger 100-500 may communicate status, operation statistics, identification, sensor data, usage information, maintenance data, and the like.

Using the external device 800, a user can access operational parameters of the battery pack charger 100-500 and battery packs 685 that are coupled to the battery pack charger 100-500. The operational parameters may include whether the battery pack 685 is being charged, a tool connected to the battery pack 685, a charge status (e.g., a charge level) of the battery pack 685, a number of tool operations remaining for a tool connected to the battery pack 685, a temperature of the battery pack 685, a temperature of the charger 100-500, and the like. The external device 800 can also transmit data to the battery pack charger 100-500 for charger configuration, firmware updates, or to send commands. The external device 800 also allows a user to set operational parameters, safety parameters, select other operational modes, and the like for the battery pack charger 100-500.

The external device 800 is, for example, a smart phone (as illustrated), a laptop computer, a tablet computer, a personal digital assistant (PDA), a smart watch, a buzzer, or another electronic device capable of communication wirelessly with the battery pack charger 100-500 and providing a user interface. The external device 800 includes a controller (similar to controller 600 and including a processing device and a memory) and provides the user interface and allows a user to access and interact with the battery pack charger 100-500. The external device 800 can receive user inputs to determine operational parameters, enable or disable features, and the like. The user interface of the external device 800 provides an easy-to-use interface for the user to control and customize operation of the battery pack charger 100-500. The external device 800, therefore, grants the user access to the operational data of the battery pack charger 100-500, and provides a user interface such that the user can interact with the controller 600 of the battery pack charger 100-500.

In addition, as shown in FIG. 8, the external device 800 can also share operational data obtained from the battery pack charger 100-500 with a remote server 810 connected through a network 815. The remote server 810 may be used to store the operational data obtained from the external device 800, provide additional functionality and service to the user, or a combination thereof. In some embodiments, storing the information on the remote server 810 allows a user to access the information from a plurality of different locations. In some embodiments, the remote server 810 collects information from various users regarding their devices and provide statistics or statistical measures to the user based on information obtained from the different devices. The network 815 may include various networking elements (routers 820, hubs, switches, cellular towers 825, wired connections, wireless connections, etc.) for connecting to, for example, the Internet, a cellular data network, a local network, or a combination thereof as previously described. In some embodiments, the battery pack charger 100-500 is configured to communicate directly with the server 810 through an additional wireless interface or with the same wireless interface that the battery pack charger 100-500 uses to communicate with the external device 800.

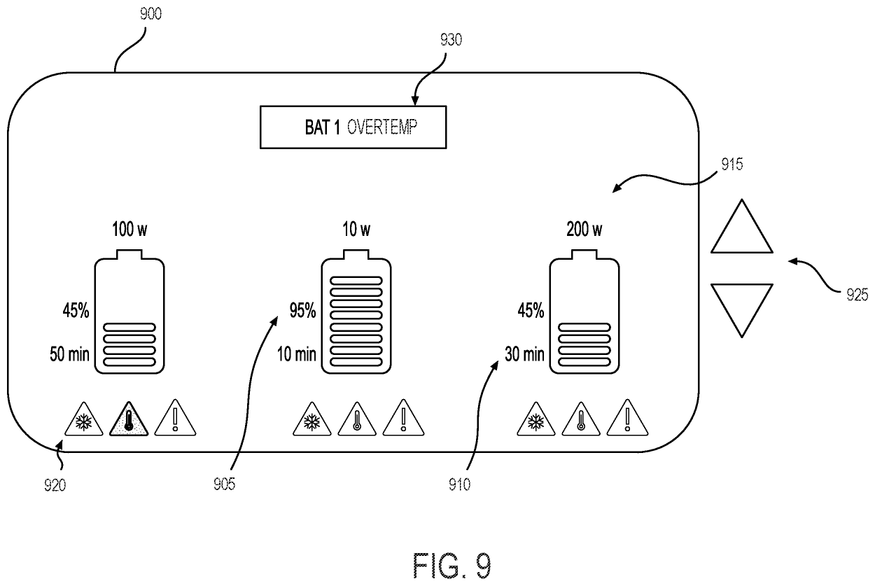

In some embodiments, the charger 100-500 includes a display or screen integrated on its housing. FIG. 9 illustrates a display 900 provided on the screen. The display 900 provides information related to battery packs 685 coupled to the charger 100-500. For example, the display 900 may provide a percent charge of each battery pack 685 (indicated by a first graphical indicator 905), a time remaining until each battery pack 685 is fully charged (indicated by a second graphical indicator 910), the charge power (for example, in Watts) of each battery pack 685 (indicated by a third graphical indicator 915), and fault indicators for each battery pack 685 (indicated by a fourth graphical indicator 920). In some embodiments, the display 900 includes arrows 925 that, when selected, scroll the display up or down. For example, if six battery packs are coupled to the charger 100-500, but only information regarding battery packs 1-3 can be displayed at a time, the arrows 925 provide a user the ability to scroll to see information regarding battery packs 4-6.

The display 900 may provide diagnostic information related to each battery pack 685 coupled to the charger 100-500. For example, each battery pack 685 may have a plurality of fault indicators (e.g., the fourth graphical indicator 920), such as temperature indicators, overcharge indicators, and the like. The display 900 may further provide a detailed fault message 930 describing the fault in more detail than provided by the fourth graphical indicator 920. The display 900 may also include a number of charge cycles, charger power consumption, an average power use, a number of previous faults, and other diagnostic information for each battery pack 685 and the charger 100-500.

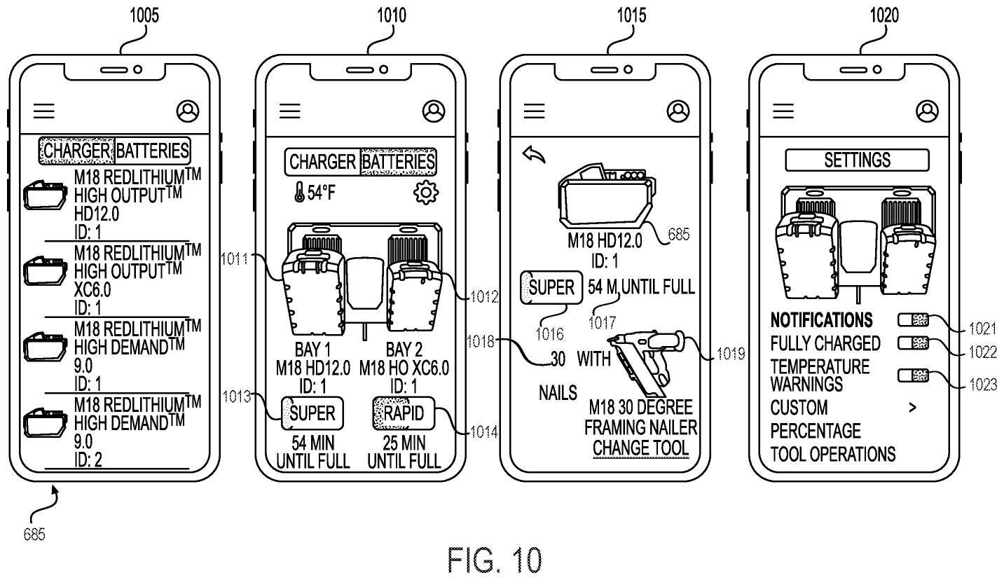

In some embodiments, information regarding the battery pack(s) 685 and the charger 100-500 is provided via a mobile application of the external device 800. For example, FIG. 10 provides a user interface of a mobile application according to various embodiments. Specifically, FIG. 10 provides a first user interface 1005, a second user interface 1010, a third user interface 1015, and a fourth user interface 1020.

The first user interface 1005 provides a plurality of individual battery packs 685 that are registered with the mobile application. The first user interface 1005 may also display, for each battery pack 685, a battery pack type, a name of the battery pack 685, and an identification number associated with each battery pack 685. In some embodiments, the first user interface 1005 also provides similar information for any charger 100-500 that is registered with the mobile application.

Selection of one of the battery packs 685 displayed on the first user interface 1005 may result in a transition to the third user interface 1015. The third user interface 1015 provides the selected battery pack 685, a charge status (e.g., a charge level) of the selected battery pack 685 (provided by charge indicator 1016), and a remaining period of time until the selected battery pack 685 is completely charged (provided by time indicator 1017). In some embodiments, the battery pack 685 may be coupled to a power tool. Accordingly, the third user interface 1015 may also provide information related to the connected power tool (provided by tool indicator 1019). The third user interface 1015 may also show a remaining number of tool operations until the battery pack 685 is completely discharged (provided by capacity indicator 1018). In such embodiments, the battery pack 685 includes a wireless communication controller 630 for communicating with the external device 800 as previously described. In some embodiments, a user may select a specific power tool registered with the mobile application to observe a remaining number of tool operations for the selected power tool.

Selection of a charger 100-500 displayed on the first user interface 1005 may result in a transition to the second user interface 1010. The second user interface 1010 provides information related to the selected charger 100-500 and any battery packs 685 coupled to the selected charger 100-500. For example, in the illustrated example, the second user interface 1010 provides a first battery pack 1011 and a second battery pack 1012 coupled to the charger 100. The second user interface 1010 also provides the charge status and remaining charge time for each battery pack 685 coupled to the charger 100-500. In the illustrated example of the second user interface 1010, a first charge indicator 1013 provides the charge status and remaining charge time for the first battery pack 1011, and a second charge indicator 1014 provides the charge status and remaining charge time for the second battery pack 1012.

In some embodiments, a user of the external device 800 may be able to customize notifications and operations of the charger 100-500 and/or the battery pack 685 using the mobile application. For example, fourth user interface 1020 provides a settings window in which notifications may be toggled (e.g., turned on or off) and customized via a toggle input graphic. For example, using the fourth user interface 1020, a user may toggle all notifications using a first toggle input graphic 1021. A user may toggle, using the fourth user interface 1020, receiving notifications when a battery pack 685 is charged using a second toggle input graphic 1022. In some embodiments, a user may toggle a setting to receive notifications when a battery pack 685 is at 50% charge instead of or in addition to receiving a notification when the battery pack 685 is fully charged. Additionally, using the fourth user interface 1020, users may toggle temperature notifications and fault notifications using a third toggle input graphic 1023.

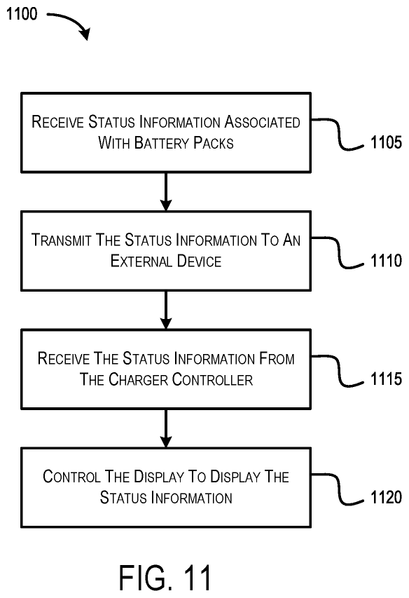

FIG. 11 provides a method 1100 for providing notifications indicative of a status of the battery pack 685. The method 1100 is performed by the controller 600, the external device 800, or a combination thereof. At block 1105, the controller 600 receives status information associated with the battery pack 685. In embodiments of the charger 100, 200, 300, 400, 500 where multiple battery packs 685 connect to the charger 100, 200, 300, 400, 500, the controller 600 receives status information associated with each connected battery pack 685. At block 1110, the controller 600 transmits, with the wireless communication controller 630, the status information to the external device 800.

At block 1115, the external device 800 receives the status information from the controller 600. At block 1120, the external device 800 controls a display to display the status information. For example, the external device 800 implements a mobile application to provide the first user interface 1005, the second user interface 1010, the third user interface 1015, or the fourth user interface 1020, as previously described.

Thus, embodiments provided herein describe, among other things, systems and methods for providing notifications regarding battery pack charging status.

What is claimed is:

1. A charging system comprising:
a battery charger including:
a housing,
a battery pack interface configured to receive a plurality of power tool battery packs,
a wireless communication controller configured to communicate with an external device, and
a charger controller connected to the battery pack interface and the wireless communication controller, the charger controller configured to:
receive status information associated with each of the plurality of power tool battery packs, and
transmit, with the wireless communication controller, the status information to the external device; and
the external device including:
a display; and
an external device controller connected to the display, the external device controller configured to:
receive the status information from the charger controller, and
control the display to display the status information via a user interface.

2. The charging system of claim 1, wherein:
the battery charger includes one or more voltage sensors configured to sense a charge voltage of each of the plurality of power tool battery packs; and
the status information includes the charge voltage of each of the plurality of power tool battery packs.

3. The charging system of claim 1, wherein the external device controller is further configured to:
provide, via the user interface, a plurality of graphical indicators, each of the plurality of graphical indicators associated with one of the plurality of power tool battery packs connected to the battery pack interface.

4. The charging system of claim 3, wherein the external device controller is further configured to:
receive, via the display, a selection of one of the plurality of graphical indicators associated with one of the plurality of power tool battery packs; and
provide, via the user interface and in response to the selection of the one of the plurality of graphical indicators, the status information associated with the selected power tool battery pack.

5. The charging system of claim 1, wherein the battery charger is one of a plurality of battery chargers, and wherein the external device controller is further configured to:
provide, via the user interface, a plurality of graphical indicators, each of the plurality of graphical indicators associated with one of the plurality of battery chargers.

6. The charging system of claim 5, wherein the external device controller is further configured to:
receive, via the display, a selection of one of the plurality of graphical indicators associated with the battery charger; and
provide, via the user interface and in response to the selection of the one of the plurality of graphical indicators, the status information associated with each power tool battery pack connected to the battery interface.

7. The charging system of claim 1, wherein the status information includes at least one selected from a group consisting of charge capacity of each power tool battery pack, a remaining charge time of each power tool battery pack, a type of each power tool battery pack, and an identification number of each power tool battery pack.

8. The charging system of claim 1, wherein the external device controller is further configured to:
provide, via the display, a first toggle input graphic;
receive, via the display, a selection of the first toggle input graphic; and
provide, in response to selection of the first toggle input graphic and in response to one of the plurality of battery packs being fully charged, a notification indicative of the battery pack being charged on the display.

9. The charging system of claim 8, wherein the external device controller is further configured to:
provide, via the display, a second toggle input graphic;
receive, via the display, a selection of the second toggle input graphic; and
provide, in response to selection of the second toggle input graphic and in response to one of the plurality of battery packs having a fault condition, a notification indicative of the fault condition on the display.

10. A method for notifying battery pack status, the method comprising:
receiving, with a battery pack charger, status information associated with a plurality of power tool battery packs connected to the battery pack charger, wherein the battery pack charger includes a housing;
transmitting, with a wireless communication controller, the status information to an external device;
receiving, with the external device, the status information from the charger controller; and
controlling, with the external device, a display to display the status information via a user interface.

11. The method of claim 10, further comprising:
providing, via the user interface, a plurality of graphical indicators, each of the plurality of graphical indicators associated with one of the plurality of power tool battery packs connected to the battery pack charger.

12. The method of claim 11, further comprising:
receiving, via the display, a selection of one of the plurality of graphical indicators associated with one of the plurality of power tool battery packs; and
providing, via the user interface and in response to the selection of the one of the plurality of graphical indicators, the status information associated with the selected power tool battery pack.

13. The method of claim 10, wherein the battery charger is one of a plurality of battery chargers, and wherein the method further comprises:
providing, via the user interface, a plurality of graphical indicators, each of the plurality of graphical indicators associated with one of the plurality of battery chargers.

14. The method of claim 13, further comprising:
receiving, via the display, a selection of one of the plurality of graphical indicators associated with the battery charger; and
providing, via the user interface and in response to the selection of the one of the plurality of graphical indicators, the status information associated with each power tool battery pack connected to the battery interface.

15. The method of claim 10, further comprising:
providing, via the display, a first toggle input graphic;
receiving, via the display, a selection of the first toggle input graphic; and
providing, in response to selection of the first toggle input graphic and in response to one of the plurality of battery packs being fully charged, a notification indicative of the battery pack being charged on the display.

16. The method of claim 10, further comprising:
providing, via the display, a second toggle input graphic;
receiving, via the display, a selection of the second toggle input graphic; and
providing, in response to the selection of the second toggle input graphic and in response to one of the plurality of battery packs experiencing a fault condition, a notification indicative of the fault condition on the display.

17. A battery charger comprising:
a housing;
a display;
a battery pack interface configured to receive a power tool battery pack; and
a charger controller connected to the battery pack interface and the display, the charger controller configured to:
receive status information associated with the power tool battery pack, and
provide, on the display, a plurality of indicators indicative of the status information.

18. The battery charger of claim 17, wherein the plurality of indicators includes at least one selected from the group consisting of a first indicator configured to indicate a charge status of the power tool battery pack, a second indicator configured to indicate a remaining charge time of the power tool battery pack, and a third indicator configured to indicate a fault condition of the power tool battery pack.

19. The battery charger of claim 17, wherein the battery pack interface is configured to receive a plurality of power tool battery packs, and wherein the charger controller is further configured to:
receive the status information associated with each of the plurality of power tool battery packs, and
provide, on the display, the plurality of indicators indicative of the status information of each power tool battery pack.

20. The battery charger of claim 19, wherein the charger controller is further configured to:
provide, on the display, a first subset of the plurality of indicators associated with a first subset of the plurality of power tool battery packs;
receive, on the display, an input to scroll the display; and
provide, in response to the input and on the display, a second subset of the plurality of indicators associated with a second subset of the plurality of power tool battery packs.
